(19) United States
(12) Patent Application Publication
(10) Pub. No.: US 2009/0121765 A1
(43) Pub. Date: May 14, 2009

(54) LATCH CIRCUIT AND FLIP-FLOP CIRCUIT

(75) Inventor: Hiroshi YAMAMOTO, Kanagawa (JP)

Correspondence Address: YOUNG & THOMPSON, 209 Madison Street, Suite 500, ALEXANDRIA, VA, 22314, US

(73) Assignee: NEC ELECTRONICS CORPORATION, KANAGAWA (JP)

(21) Appl. No.: 12/264,540

(22) Filed: Nov. 4, 2008

(30) Foreign Application Priority Data
Nov. 8, 2007 (JP) 2007-291060

(51) Int. Cl. H03K 3/356; H03K 3/00

(52) U.S. Cl. 327/208; 327/199; 327/215

(57) ABSTRACT

A latch circuit includes: first nodes which are three or more and to which a voltage in a first signal level is set; second nodes which are three or more and to which a voltage in a second signal level obtained by inverting the first signal level is set; and first node voltage control circuits having the first nodes; and second node voltage control circuits having the second nodes. Each of the first node voltage control circuits is connected with at least two of the three or more second nodes, and controls the voltage of the first node based on the voltages of the at least two second modes. Each of the second node voltage control circuits is connected with at least two of the three or more first nodes and controls the voltage of the second node based on the voltages of the at least two first nodes.

### INCORPORATION BY REFERENCE

This patent application claims priority on convention based on Japanese Patent Application No. 2007-291060. The disclosure thereof is incorporated herein by reference.

### BACKGROUND OF THE INVENTION

1. Field of the Invention

The present invention relates to a latch circuit and a flip-flop circuit that uses it.

2. Description of Related Art

In recent years, it is known that a soft error is caused by high-energy radiation (alpha ray and neutron beam) irradiating the latch circuit. The soft error is a failure caused by “singe-event upset (SEU)” in which data is inverted, resulting from a phenomenon that alpha rays and/or neutron beams are incident on the latch circuit to generate electric charges and the electric charges are collected by a region (node) for retaining the data. The soft error is a transient failure, and if correct data can be rewritten anew, the latch circuit will operate normally again. However, even if it is temporary, since the stored data is inverted, there is a case that its influence takes effect in the whole computer system.

The soft error occurring in a conventional latch circuit shown in FIG. 1 will be described as one example. FIG. 1 is a circuit diagram showing a fundamental configuration of the latch circuit. Here, a transfer gates connected to a node N10A or/and a node N20B is omitted.

A case where collection of electric charges occurs in a state that the node N10A is set to “1” (high level) and the node N20B is set to “0” (low level) will be described. In an initial stage, since a voltage in the node N10A is in the high level, a P-channel type MOS transistor MP10B is maintained in an ON state, and an N-channel type MOS transistor MN10B is maintained in the OFF state. Moreover, since a voltage in the node N20B is in the low level, a P-channel type MOS transistor MP10A is maintained in an OFF state, and an N-channel type MOS transistor MN10A is maintained in the ON state. Here, if radiation is allowed to be incident on near the node N10A, electrons are collected in the node N10A, so that the data set to the node N10A is inverted from “1” to “0” (the node N10A changes from the high level to the low level). At this time, since gate voltages of the P-channel type MOS transistor MP10B and the N-channel type MOS transistor MN10B change to the low level, the P-channel type MOS transistor MP10B changes from the OFF state to the ON state, and the N-channel type MOS transistor MN10B changes from the ON state to the OFF state. Thereby, a voltage of the node N20B changes to the high level. That is, the data set to the node N20B is inverted from “0” to “1.” Thus, the latch circuit shown in FIG. 1 will continue to hold an inverted state of the data that should be latched originally.

As a semiconductor memory device that is hardened against such a soft error, a DICE (Dual Interlocked Cell) is known. FIG. 2 shows a fundamental configuration of the conventional DICE. In the DICE shown in FIG. 2, even if collection of electric charges takes place at one node, the soft error does not occur essentially. Referring to FIG. 2, a principle of suppressing the soft error in the DICE will be described.

The DICE is provided with nodes N10A and N10C at which data of a same signal level are set, and nodes N20B and N20D at which inverted data of the above data set to the nodes N10A, N10C are set. For example, when the nodes N10A and N10C are set to the data “1,” the nodes N20B and N20D are set to the data “0.” In this case, since the voltages in the nodes N10A and N10C are in the high level, the P-channel type MOS transistors MP10B and MP10D are maintained in the OFF state, and the N-channel type MOS transistors MN10B and MN10D are maintained in the ON state. Moreover, since the voltages in the nodes N20B and N20D are in the low level, the P-channel type MOS transistors MP10A and MP10C are maintained in the ON state, and the N-channel type MOS transistors MN10A and MN10C are maintained in the OFF state.

Here, if radiation is incident near the node N10A, electric charges will be collected in the node N10A, and the data set to the node N10A will be inverted from “1” to “0” (transition from the high level to the low level). At this time, since gate voltages of the P-channel type MOS transistor MP10B and the N-channel type MOS transistor MN10D change to the low level, the P-channel type MOS transistor MP10B changes from the OFF state to the ON state, and the N-channel type MOS transistor MN10D changes from the ON state to the OFF state. On the other hand, at this time, the N-channel type MOS transistor MN10B and the P-channel type MOS transistor MP10D are still in the ON state and in the OFF state, respectively. Therefore, the voltages of the nodes N20B and N20D change from the low level to an unstable level (indeterminate value) that is neither the low level nor the high level. This voltage change propagates to the P-channel type MOS transistor MP10C and the N-channel type MOS transistor MN10C, and also affects a voltage of the node N10C after a predetermined time. However, since it takes a certain time until the voltage of the node N10C is stabilized, during that time the node N10C can maintain the high-level voltage. That is, even if the data “1” of the node N10A is inverted to data “0.” the node N10C continues to hold the data “1” for a while. If charge collection in the node N10A ends during this time, the voltage of each node can return by the voltage maintained in the node N10C. Thus, in the DICE, since the soft error is suppressed even if the charge collection occurs in a single node, a soft error rate of the latch circuit can be reduced.

Moreover, as another example, a technique of improving the soft error rate of the latch circuit is described in Japanese Patent Application Publication (JP-P2006-129477A: related art 1). A semiconductor circuit described in the related art 1 is provided with two inverters, each of whose output and input are connected for feed back and when an input of the one inverter suffers a failure by charge collection, the inverter is made to be in a tristate or in a high impedance state by a control signal, whereby the soft error rate is improved.

In recent years, a problem has been pointed out, of charge sharing that electric charges generated by one time of incidence of radiation are collected by two or more nodes. The problem of charge sharing will be described in “Single Event Upsets in a 130 nm Hardened Latch Design Due to Charge Sharing” by 0. Amusan, et al. (45th Annual International Reliability Physics Symposium, IEEE Proceedings, United States, 2007, pp. 306-311) as a related art 2, and “Assessing the impact of scaling on the efficacy of spatial redundancy based SER mitigation schemes for terrestrial applications” by N. Seifert et al. (IEEE Workshop on Silicon Errors in Logic-System Effects, United States, 2007, which was searched on Oct. 23, 2007, on the Internet (URL: http://www.seise.org/selse07.program.linked.htm)) as a related art 3. Although the DICE shown in FIG. 2 can suppress the soft error resulting from the charge collection in one node, latched data is inverted and the soft error will occur when the charge collection occurs in two or more nodes.

For example, in the above example, when the charge collection has occurred in the two nodes N10A and N10C simultaneously, the P-channel type MOS transistors MP10B and MP10D change from the OFF state to the ON state almost simultaneously, and the N-channel type MOS transistors MN10B and MN10D change from the ON state to the OFF state almost simultaneously. In this case, similarly with the principle described above, not only the nodes N10A and N10C, on which radiation has been incident, but also the nodes N20B and N20D, on which no radiation has been incident, invert their values immediately. For this reason, also, in the whole DICE, it will be stabilized in a state that the latched data is inverted.

Similarly to a technique described in the related art 1, there is a case that, when the charge collection has occurred in a plurality of nodes, the soft error cannot be suppressed depending on the positions of the charge collection.

As described above, in the conventional technique, it is impossible to suppress the soft error when a plurality of memory nodes collected the electric charges by charge sharing. For this reason, further improvement of a rate of the soft error occurring in the latch circuit is demanded.

### SUMMARY

In an aspect of the present invention, a latch circuit includes: first nodes which are three or more and to which a voltage in a first signal level is set; second nodes which are three or more and to which a voltage in a second signal level obtained by inverting the first signal level is set; and first node voltage control circuits having the first nodes; and second node voltage control circuits having the second nodes. Each of the first node voltage control circuits is connected with at least two of the three or more second nodes, and controls the voltage of the first node based on the voltages of the at least two second modes. Each of the second node voltage control circuits is connected with at least two of the three or more first nodes and controls the voltage of the second node based on the voltages of the at least two first nodes.

In another aspect of the present invention, a flip-flop circuit includes: two latch circuits; and a clock signal generating circuit configured to supply the two latch circuits. Each of the latch circuit includes: first nodes which are three or more and to which a voltage in a first signal level is set; second nodes which are three or more and to which a voltage in a second signal level obtained by inverting the first signal level is set; and first node voltage control circuits having the first nodes; and second node voltage control circuits having the second nodes. Each of the first node voltage control circuits is connected with at least two of the three or more second nodes, and controls the voltage of the first node based on the voltages of the at least two second modes. Each of the second node voltage control circuits is connected with at least two of the three or more first nodes and controls the voltage of the second node based on the voltages of the at least two first nodes. One of the two latch circuits function as a latch circuit on an input side in which data is supplied to the second node through the transfer gates and the other functions as the latch circuit on an output side in which the data latched in the first node is outputted. The first node of the latch circuit on the input side is connected with the second node of the latch circuit on the output side through the transfer gate in the latch circuit on the output side.

According to the present invention, it is possible to reduce a rate of soft error in the latch circuit. Moreover, it is possible to suppress an occurrence of soft error resulting from the charge sharing in the latch circuit.

### BRIEF DESCRIPTION OF THE DRAWINGS

The above and other objects, advantages and features of the present invention will be more apparent from the following description of certain embodiments taken in conjunction with the accompanying drawings, in which:

FIG. 1 is a circuit diagram showing a fundamental configuration of a conventional latch circuit;

FIG. 2 is a circuit diagram showing a configuration of a conventional DICE circuit;

FIG. 3 is a voltage waveform diagram showing a simulation result of a node voltage when charge collection is performed in two nodes in the conventional DICE circuit;

FIG. 4 is a circuit diagram showing a configuration of a latch circuit according to a first embodiment of the present invention;

FIG. 5 is a voltage waveform diagram showing a simulation result of a node voltage when charge collection is performed in two nodes in the latch circuit according to the first embodiment of the present invention;

FIG. 6 is a circuit diagram showing one example of a configuration of a latch circuit according to a second embodiment of the present invention;

FIG. 7 is a circuit diagram showing the configuration of the latch circuit according to a third embodiment of the present invention;

FIG. 8 is a circuit diagram showing the configuration of the latch circuit according to a modification of the third embodiment of the present invention;

FIGS. 9A and 9B are circuit diagrams showing the configuration of a flip-flop circuit using the latch circuits according to the present invention; and

FIG. 10 is a circuit diagram showing a configuration of a clock signal generating circuit for generating a clock signal used by the flip-flop circuit.

### DESCRIPTION OF THE PREFERRED EMBODIMENTS

Hereinafter, a latch circuit according to the present invention will be described with reference to the attached drawings. In the drawings, the same or similar reference numerals designate the same or similar components, respectively.

### First Embodiment

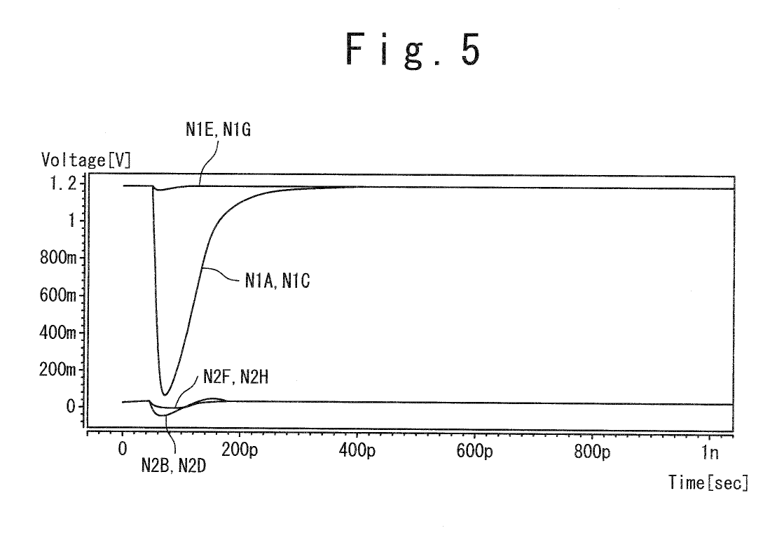

FIG. 4 is a circuit diagram showing a configuration of a latch circuit 10 according to a first embodiment of the present invention. The latch circuit 10 in the first embodiment is provided with three or more nodes N1A, N1C, N1E, and N1G as first nodes in which a voltage in a first signal level is set and three or more nodes N2B, N2D, N2F, and N2H as second nodes in which a voltage in a second signal level obtained by inverting the first signal level is set. For example, when a data “1” is set in the nodes N1A, N1C, N1E, and N1G, a data “0” obtained by inverting the data “1” is set in the nodes N2B, N2D, N2F, and N2H. Here, transfer gates (not illustrated) are connected to the nodes N1A, N1C, N1E, and N1G as the first nodes and receive a data to be latched by the latch circuit through the nodes N1A, N1C, N1E, and N1G. Further, transfer gates may be connected between the nodes N1A, N1C, N1E, and N1G as the first nodes and the nodes N2B, N2D, N2F and N2H as the second nodes. Hereinafter, the plurality of first nodes and the plurality of second nodes are called data holding nodes. However, the latch circuit 10 shown in FIG. 4 includes transfer gates connected to the data holding nodes and controlling receiving and holding of a data. For example, the latch circuit 10 includes a transfer gate connected in correspondence to the second node and controlling input of a data to the second node.

Moreover, the latch circuit in the first embodiment has the data holding nodes and is provided with node voltage control circuits 1A, 1B, 1C, 1D, 1E, 1F, and 1G for controlling voltages of the data holding nodes.

Each of the node voltage control circuits 1A, 1C, 1E, and 1G includes a P-channel type MOS transistor and an N-channel type MOS transistor whose drains are connected through a corresponding one of the nodes N1A, N1C, N1E, and N1G. Moreover, each of the node voltage control circuits 1A, 1C, 1E, and 1G is provided with a transistor that is connected in series through the drain and the source between the power supply and the transistor connected to the node N1A, N1C, N1E, or N1G. The gates of the plurality of transistors that are connected in series between the each of the nodes and the power supply are connected to different ones of the nodes N2B, N2D, N2F, and N2H, respectively.

For example, the node voltage control circuit 1A is provided with a P-channel type MOS transistor MP1A and an N-channel type MOS transistor MN1A whose drains are connected through the node N1A. The node voltage control circuit 1A is further provided with a P-channel type MOS transistor MP2A that is connected in series between a source of the P-channel type MOS transistor MP1A and a first power supply (VDD), and an N-channel type MOS transistor MN2A that is connected in series between the source of the N-channel type MOS transistor MN1A and a second power supply (GND). The gates of the P-channel type MOS transistors MP1A and MP2A and the N-channel type MOS transistors MN1A and MN2A are connected to different ones of the nodes N2B, N2D, N2F, and N2H, respectively. In an example shown in FIG. 4, a gate of the P-channel type MOS transistor MP1A is connected to the node N2D, a gate of the P-channel type MOS transistor MP2A to the node N2H, a gate of the N-channel type MOS transistor MN1A to the node N2B, and the gate of the N-channel type MOS transistor MN2A to the node N2F.

Each of the node voltage control circuits 1B, 1D, 1F, and 1H is provided with the P-channel type MOS transistor and the N-channel type MOS transistor whose drains are connected through a corresponding one of the nodes N2B, N2D, N2F, and N2H. Moreover, each of the node voltage control circuits 1B, 1D, 1F, and 1H is provided with a transistor that is connected in series between the power supply and the transistor connected to the corresponding one of the nodes N2B, N2D, N2F, and N2H. The gates of a plurality of the transistors connected in series between the node and the power supply are connected to different nodes of the nodes N1A, N1C, N1E, and N1G, respectively. For example, the node voltage control circuit 1B is provided with a P-channel type MOS transistor MP1B and an N-channel type MOS transistor MN1B whose drains are connected through the node 2B. The node voltage control circuit 1B is provided with a P-channel type MOS transistor MP2B that is connected in series between the source of the P-channel type MOS transistor MP1B and the first power supply (VDD), and an N-channel type MOS transistor MN2B that is connected in series between the source of the N-channel type MOS transistor MN1B and the second power supply (GND). The gates of the P-channel type MOS transistors MP1B and MP2B and the N-channel type MOS transistors MN1B and MN2B are connected to different ones of the nodes N1A, N1C, N1E, and N1G, respectively. In an example shown in FIG. 4, the gate of the P-channel type MOS transistor MP1B is connected to the node N1A; the gate of the P-channel type MOS transistor MP2B to the node N1E; the gate of the N-channel type MOS transistor MN1B to the node N1C; and the gate of the N-channel type MOS transistor MN2B to the node N1G.

Here, in the example shown in FIG. 4, a connection relationship between a data holding node and a gate of a transistor provided in the node voltage control circuit is shown below.

Node N1A: MP1B, MN1D, MP2F, MN2H

Node N1C: MN1B, MP1D, MN2F, MP2H

Node N1E: MP2B, MN2D, MP1F, MN1H

Node N1G: MN2B, MP2D, MN1F, MP1H

Node N2B: MN1A, MP1C, MN2E, MP2G

Node N2D: MP1A, MN1C, MP2E, MN2G

Node N2F: MN2A, MP2C, MN1E, MP1G

Node N2H: MP2A, MN2C, MP1E, MN1G

In this way, one transistor is selected from each of the node voltage control circuits 1B, 1D, 1F, and 1H that control voltages of the nodes N2B, N2D, N2F, and N2H as the second nodes, and is connected to a corresponding one of the nodes N1A, N1C, N1E, and N1G as the first nodes. Similarly, one transistor is selected from each of the node voltage control circuits 1A, 1C, 1E, and 1G that control the voltages of the nodes N1A, N1C, N1E, and N1G, and is connected to a corresponding one of the nodes N2B, N2D, N2F, and N2H. Moreover, as shown in FIG. 4, it is preferable that a transistor (gate) connected to each of the data holding nodes is different for every node. That is, since the data holding nodes are connected to different transistors, a probability of a voltage variation caused by the charge collection can be reduced. However, the different data holding nodes may be connected to the same transistor (gate). Further, it is preferable that each data holding node is connected to gates of two P-channel type MOS transistors and two N-channel type MOS transistors.

By the above configuration, the semiconductor memory device according to the present invention can hold a data in the nodes N1A, N1C, N1E, and N1G, and can hold the inverted data of the data in the nodes N2B, N2D, N2F, and N2H.

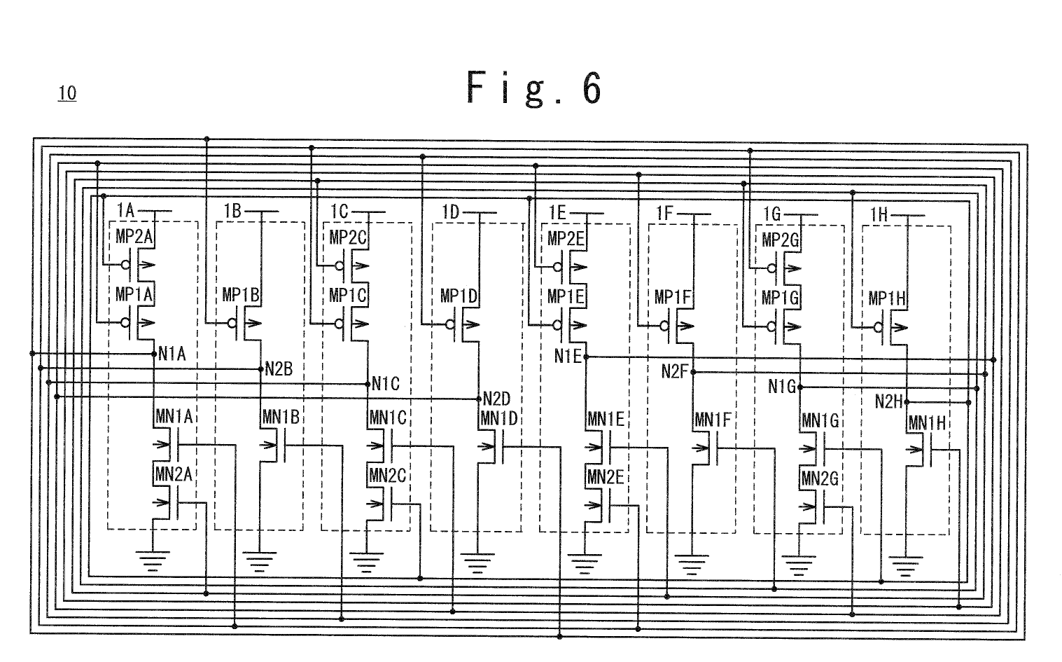

Next, referring to FIGS. 4 and 5, details of an operation when charge collection occurs in the data holding node of the latch circuit 10 according to the present invention will be described. A case that the charge collection occurs in a sate that the nodes N1A, N1C, N1E, and N1G hold “1” (high level) and the nodes N2B, N2D, N2F, and N2H hold “0” (low level). In this case, since the voltages (signal levels) in the nodes N1A, N1C, N1E, and N1G are in the high level, the P-channel type MOS transistors in the node voltage control circuits 1B, 1D, 1F, and 1H are maintained in the OFF state, and the N-channel MOS transistors in the node voltage control circuits 1B, 1D, 1F, and 1H are maintained in the ON state. Moreover, since the voltages in the nodes N2B, N2D, N2F, and N2B are in the low level, the P-channel type MOS transistors in the node voltage control circuits 1A, 1C, 1E, and 1G are maintained in the ON state, and the N-channel MOS transistors in the node voltage control circuits 1A, 1S, 1E, and 1G are maintained in the OFF state.

### <1> When Charge Collection Occurs in a Single Data Holding Node

An operation when an N type diffusion layer contained in the node NIA collects electrons by incidence of radiation, and the held data is inverted from “1” to “0” temporarily will be described. In this case, since the signal level of the node N1A changes to the low level, the P-channel type MOS transistors MP1B and MP2F change from the OFF state to the ON state, and the N-channel type MOS transistors MN1D and MN2H change from the ON state to the OFF state. Since by this change, the nodes N2D and N2H are disconnected from the first power supply (VDD) and the second power supply (GND), they change from a voltage in the low level to an intermediate voltage. On the other hand, the nodes N2B and N2F are disconnected from the first power supply (VDD) by the P-channel type MOS transistors MP2B and MP1F, and are maintained to be connected to the second power supply (GND) by the N-channel type MOS transistors MN1B and MN2B and the N-channel type MOS transistors MN1F and MN2F. For this reason, even if the P-channel type MOS transistors MP1B and MP2F change from the OFF state to the ON state, the nodes N2B and N2F continue to maintain the low level. As a result, the levels of the nodes N2D and N2H become temporarily unstable. This voltage variation propagates as a noise signal to transistors whose gates connected to the nodes N2D and N2H and also affects voltages of other nodes. However, it takes a predetermined time until the voltage variation of the nodes N2D and N2H affects the other nodes, and during that time, the other nodes maintain original correct levels. If the charge collection in the node N1A ends during this time, the voltage values of the nodes N1A, N2D, and N2H will return to states before the charge collection by the voltages maintained in the nodes N1B, N1C, N1E, N2F, and N1G.

Moreover, in the present invention, the voltage variations in the nodes N2B, N2D, N2F, and N2H are suppressed by transistors connected to the nodes with a less voltage variation. In detail, although the P-channel type MOS transistors MP1B and MP2F change from the OFF state to the ON state, the P-channel type MOS transistors MP2B and MP1F connected to the node N1E maintains the OFF state. For this reason, the P-channel type MOS transistors MP2B and MP1F function to suppress the voltage variations in the nodes N2B and N2F described above and to make the nodes N2B and N2F maintain the low level. Similarly, although the N-channel type MOS transistors MN1D and MN2H change from the ON state to the OFF state, the N-channel type MOS transistors MN2D and MN1H connected to the node N1E maintain the ON state. For this reason, the N-channel type MOS transistors MN2D and MN1H function to suppress the voltage variations in the nodes N2D and N2H described above. In detail, the voltage in the data holding node is determined based on a ratio of impedance of the P-channel type MOS transistor side and impedance of the N-channel type MOS transistor side in the node voltage control circuit to which the node belongs. Since the nodes N2D and N2H are disconnected from the second power supply (GND) by the N-channel type MOS transistors MN1D and MN2H, they cannot maintain a perfect low level. However, since the N-channel type MOS transistors MN2D and MN1H maintain the ON state, a variation of the above-mentioned impedance ratio is small, and the voltage variations in the nodes N2D and N2H are suppressed. From the above, the data having been set in the nodes N2B, N2D, N2F, and N2H become hard to vary, and the holding times of the data “1” in the nodes N1C, N1E, and N1G increase. Alternatively, the nodes N2B, N2D, N2F, and N2H maintain the data “0,” and the data “1” having been set in the nodes N1C, N1E, and N1G become hard to be inverted. For this reason, an occurrence of a soft error in the latch circuit 10 is further suppressed compared with before.

In this way, in the present invention, a plurality of transistors are connected in series between the power supply and the data holding nodes and each of their gates is connected to a different data holding node. Therefore, the voltage variation in the data holding nodes can be suppressed, so that inversion of data is prevented

### <2> When Charge Collection Occurs in Two Data Holding Nodes (Case 1)

An operation when N type diffusion layers contained in the nodes N1A and N1E collect electrons simultaneously by incidence of radiation and the both nodes are inverted from the data “1” to the data “0” simultaneously will be described. In this case, since the signal level of the node N1A changes to the low level, the P-channel type MOS transistors MP1B and MP2F change from the OFF state to the ON state and the N-channel type MOS transistors MN1D and MN2H change from the ON state to the OFF state. Moreover, since a signal level of the node N1E changes to the low level, the P-channel type MOS transistors MP2B and MP1F change from the OFF state to the ON state, and the N-channel type MOS transistors MN2D and MN1H change from the ON state to the OFF state. That is, all the P-channel type MOS transistors MP1B, MP2B, MP1D, MP2D, MP1F, MP2F, MP1H, and MP2H in the node voltage control circuits 1B, 1D, 1F, and 1H change in a switching state. Accordingly, the voltages of the nodes N2B, N2D, N2F, and N2H change from the low level to an intermediate level.

This voltage variation propagates as noise signals to transistors whose gates are connected to the nodes N2B, N2D, N2F, and N2H and affect the voltages in the nodes N1C and N1G. However, variation speeds of the voltages of the nodes N1C and N1G are moderate, compared with the nodes N2B, N2D, N2F, and N2H, and the voltage values maintain the high level for a predetermined period. That is, even when the data “1” of the node N1A in which charge collection has occurred is inverted to “0,” the nodes N1C and N1G maintain the data “1” for a while. If the charge collection in the nodes N1A and N1E ends during this time, the voltage of the each node returns to a state before the charge collection based on the voltages maintained in the nodes N1C and N1G.

In this way, according to the present invention, even when the charge collection has occurred simultaneously in two data holding nodes, it is possible to prevent generation of the soft error Mover, in this example, even when either conductive type of the transistors that control the data holding nodes changes its switching state in each of the transistor control circuits N2B, N2D, N2F, and N2H, the generation of the soft error can be suppressed.

### <3> When Charge Collection Occurs in Two Data Holding Nodes (Case 2)

An operation of a case that N type diffusion layers contained in the nodes N1A and N1C collect electrons simultaneously in response to incidence of radiation and the both of the nodes invert from a data “1” to a data “0” will be described. In this case, since the signal level of the node N1A changes to the low level, the P-channel type MOS transistors MP1B and MP2F change from the OFF state to the ON state, and the N-channel type MOS transistors MN1D and MN2H change from the ON state to the OFF state. Moreover, since a signal level of the node N1C changes to the low level, the P-channel type MOS transistors MP1D and MP2H change from the OFF state to the ON state, and the N-channel type MOS transistors MN1B and MN2F change from the ON state to the OFF state. That is, switching states change in following transistors: the P-channel type MOS transistor MP1B and the N-channel type MOS transistor MN1B of the node voltage control circuit 1B, the P-channel type MOS transistor MP1D and the N-channel type MOS transistor MN1D of the node voltage control circuit 1D, the P-channel type MOS transistor MP2F and the N-channel type MOS transistor MN2F of the node voltage control circuit 1F, and the P-channel type MOS transistor MP2H and the N-channel type MOS transistor MN2H of the node voltage control circuit 1H. Thereby, the voltages of the nodes N2B, N2D, N2F, and N2H change from the low level to the intermediate level.

This voltage variation, as described above, propagates as a noise signal to the transistors whose gates connected to the nodes N2B, N2D, N2F, and N2H, and also affects the voltages of the nodes N1E and N1G. However, the variation speeds of the voltages of the nodes N1B and N1G are moderate, compared with the nodes N2B, N2D, N2F, and N2H, and the voltages maintain the high level for a predetermined time. That is, even if the data “1” of the nodes N1A and N1C in which the charge collection has occurred are inverted to the data “0,” the nodes N1E and N1G continue to maintain the data “1” for a while. If the charge collection in the nodes N1A and N1C ends during this time, voltage values of the nodes N1A and N1C whose data are inverted and a voltage value of the data holding node set to the indeterminate level return to states before the charge collection based on voltages maintained in the nodes N1E and N1G.

Moreover, similarly to the case that the single data holding node collects electric charges, the voltage variation in the nodes N2B, N2D, N2F, and N2H are suppressed by the P-channel type MOS transistors MP2B and MP1F and the N-channel type MOS transistors MN1D and MN2H that are connected to the node N1E having a small voltage variation, and the P-channel type MOS transistors MP2D and MP1H and the N-channel type MOS transistors MN2B and MN1F connected to the node N1G. For this reason, the data having been set to the nodes N2B, N2D, N2F, and N2H become resistant to take indeterminate values, and the holding time of data “1” in the nodes N1C, N1E, and N1G increase. Otherwise, the nodes N2B, N2D, N2F, and N2H maintain the data “0,” and the data “1” of the nodes N1C, N1E, and N1G are not inverted.

In this way, in this example, even when two transistors of different conduction types change the switching state among transistors for controlling the data holding nodes in each of the transistor control circuits N2B, N2D, N2F, and N2H, the generation of the soft error can be suppressed.

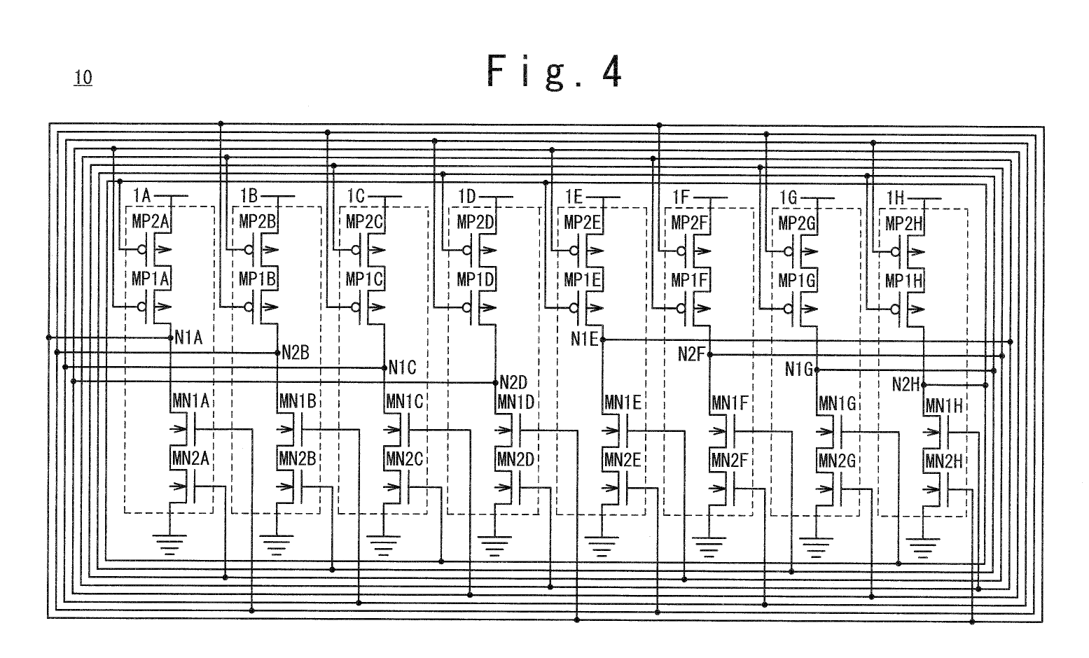

Referring to FIGS. 3 and 5, soft error resistance of the conventional technique and that of the present invention will be compared. FIG. 3 is a waveform diagram showing a variation of the voltage value (simulation value) of the data holding node in the conventional latch circuit when the charge collection has occurred simultaneously in two data holding nodes. FIG. 5 is a waveform diagram showing a variation of the voltage value (simulation value) of the data holding node in the latch circuit according to the present invention when the charge collection occurs simultaneously in two data holding nodes.

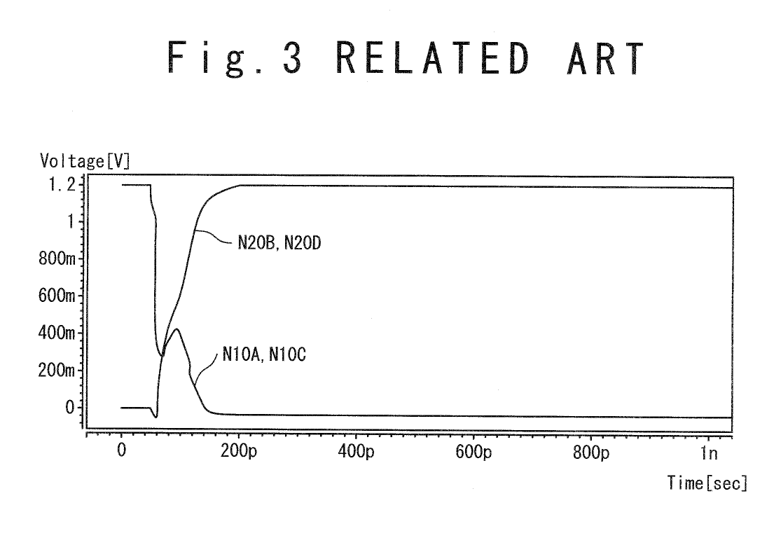

Referring to FIG. 3, it is supposed that a predetermined quantity of electric charges are simultaneously injected (current is supplied) into the nodes N10A and N10C in the DICE shown in FIG. 2. When the nodes N10A and N10C start inversion, the nodes N20B and N20DB also start inversion immediately, and this inversion propagates to other data holding nodes. Then, all the data holding nodes are inverted and become stabilized (soft error).

Referring to FIG. 5, it is supposed that a predetermined quantity of electric charges is simultaneously injected into the nodes N1A and N1C in the latch circuit 10 shown in FIG. 4. Even when the nodes N1A and N10C start inversion, the input signals of the P—channel type MOS transistors MP1B and MP2B and the N-channel type MOS transistors MN1B and MN2B are not affected, and therefore the nodes N1E and N1G continue to hold correct values. As described above, although the P-channel type MOS transistor MP1B and the N-channel type MOS transistor MN1B are affected by the noise from the node NIA and the node N1C, the input signals of the P-channel type MOS transistor MP2B and the N-channel type MOS transistor MN2B are not affected. For this reason, the voltage value of the node N2B hardly changes. Similarly, the voltage values of the nodes N2D and N2F, and N2H hardly change. As a result, although noises are temporarily supplied only into the node N1A and the node N1C into which the electric charges have been injected directly, the signal levels of the other data holding nodes are stable; therefore, the voltage values of the node N1A and the node N1C recover correct values, and the soft error does not occur.

As described above, according to the present invention, even if the charge collection has occurred in two nodes by charge sharing, the generation of the soft error can be suppressed (there is no occurrence of the soft error actually). It should be noted that even when a combination of two data holding nodes for collecting electric charges is different from the example shown in the above, the generation of the soft error can be suppressed similarly.

### <4> When the Charge Collection Occurs in Three Data Holding Nodes

N type diffusion layers contained in the nodes N1A, N1C, and N1E may collect electrons simultaneously by incidence of radiation and the both nodes may be inverted from the data “1” to the data “0” simultaneously. An operation of such a case will be described. In this case, since the signal level of the node N1A changes to the low level, the P-channel type MOS transistors MP1B and MP2F change from the OFF state to the ON state and the N-channel type MOS transistors MN1D and MN2H change from the ON state to the OFF state. Moreover, since the signal level of the node N1C changes to the low level, the P-channel type MOS transistors MP1D and MP2H change from the OFF state to the ON state and the N-channel type MOS transistors MN1B and MN2F change from the ON state to the OFF state. Further, since the signal level of the node N1E changes to the low level, the P-channel type MOS transistors MP2B and MP1F change from the OFF state to the ON state and the N-channel type MOS transistors MN2D and MN1H change from the ON state to the OFF state. That is, switching states change in the following transistors: the P-channel type MOS transistors MP1B and MP2B and the N-channel type MOS transistor MN1B of the node voltage control circuit 1B, the P-channel type MOS transistor MP1D and the N-channel type MOS transistors MN1D and MP2D of the node voltage control circuit 1D, the P-channel type MOS transistors MP1F and MP2F and the N-channel type MOS transistor MN2F of the node voltage control circuit 1F, and the P-channel type MOS transistor MP2H and the N-channel type MOS transistors MN1H and MN2H of the node voltage control circuit 1H. Thereby, the voltages of the nodes N2B, N2D, N2F, and N2H change from the low level to an intermediate level.

This voltage variation propagates as a noise signal to transistors whose gates are connected to the nodes N2B, N2D, N2F, and N2H, as described above, and also affects the voltage of the node N1G. However, the variation speed of the voltage of the node N1G is moderate, compared with the nodes N2B, N2D, N2F, and N2H, and the voltage of the node N1G maintains the high level. That is, even if the data “1” of the nodes N1A, N1C, and N1E in which the charge collection has occurred is inverted to the data “0,” the node N1G maintains the data “1” for a while. If the charge collection in the nodes N1A, N1C, and N1E ends during this time, the voltage values of the data holding nodes N1A, N1C, and N1E whose data are inverted and the voltage value of the data holding node whose voltage has been an indeterminate value return to the states before the charge collection by the voltage maintained in the node N1G.

As described above, according to the present invention, even if the charge collection has occurred in two nodes by charge sharing, the generation of the soft error can be suppressed. It should be noted that even if a combination of three data holding nodes that collect the electric charges is different from the example shown above, it is possible to suppress the occurrence of the soft error similarly.

### Second Embodiment

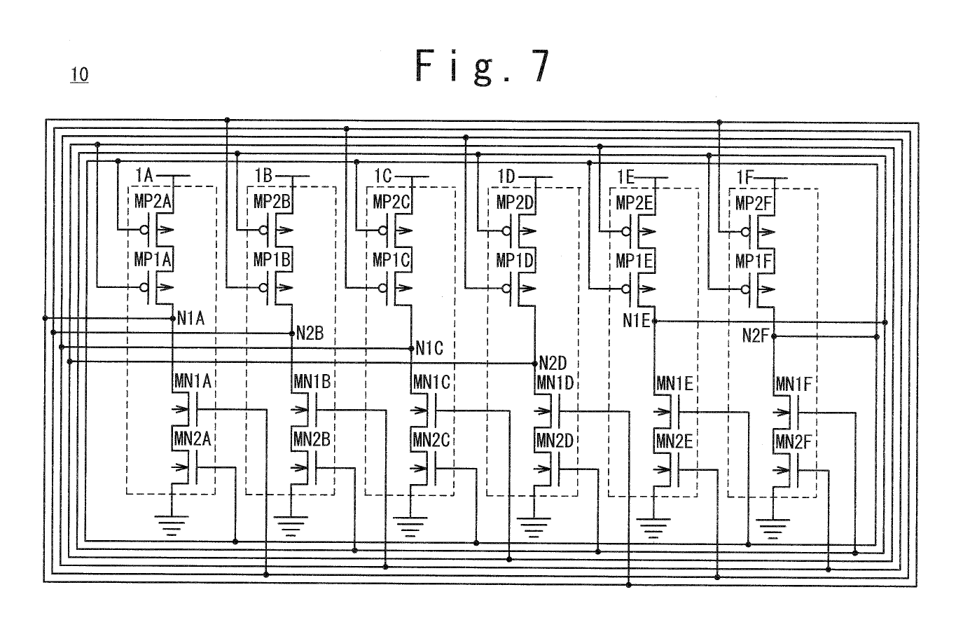

The latch circuit 10 shown in FIG. 4 may be altered in a part of its configuration. For example, any of the P-channel type MOS transistors MP1A to the N-channel type MOS transistor MN2H for suppressing the voltage value of the data holding node may be removed from the latch circuit 10 shown in FIG. 4. FIG. 6 is a circuit diagram showing the latch circuit 10 according to a second embodiment of the present invention. In the latch circuit 10 shown in FIG. 6, the P-channel type NOS transistors MP2B, MP2D, MP2F, and MP2H and the N-channel type MOS transistors MN2B, MN2D, MN2F, and MN2H are removed from the configuration of the latch circuit 10 shown in FIG. 4.

Since the transistors with smaller influence of the noise signal are removed in the latch circuit 10 shown in FIG. 6, the latch circuit 10 has an effect of a reduced circuit area although it has a higher generation rate of soft error than the circuit shown in FIG. 4. It is effective to use the circuit shown in FIG. 6 instead of the circuit shown in FIG. 4, depending on a requisition of the soft error resistance. Although the transistors between the nodes N2A, N2C, N2E, and N2G for holding the same data and the power supply have been reduced in the one example shown in FIG. 6, the transistors to be removed can be arbitrarily set, not being restricted to the above example. However, although the number of transistors to be removed is arbitrary, each of all the node voltage control circuits 1A to 1H must be provided with the P-channel type MOS transistor and the N-channel type MOS transistor that are connected to each other through the node. For example, in case of the node voltage control circuit 1A, the P-channel type MOS transistor MP2A and the N-channel type MOS transistor MN2A may be reduced arbitrarily, but the P-channel type MOS transistor MP1A and the N-channel type MOS transistor MN1A are not reduced.

### Third Embodiment

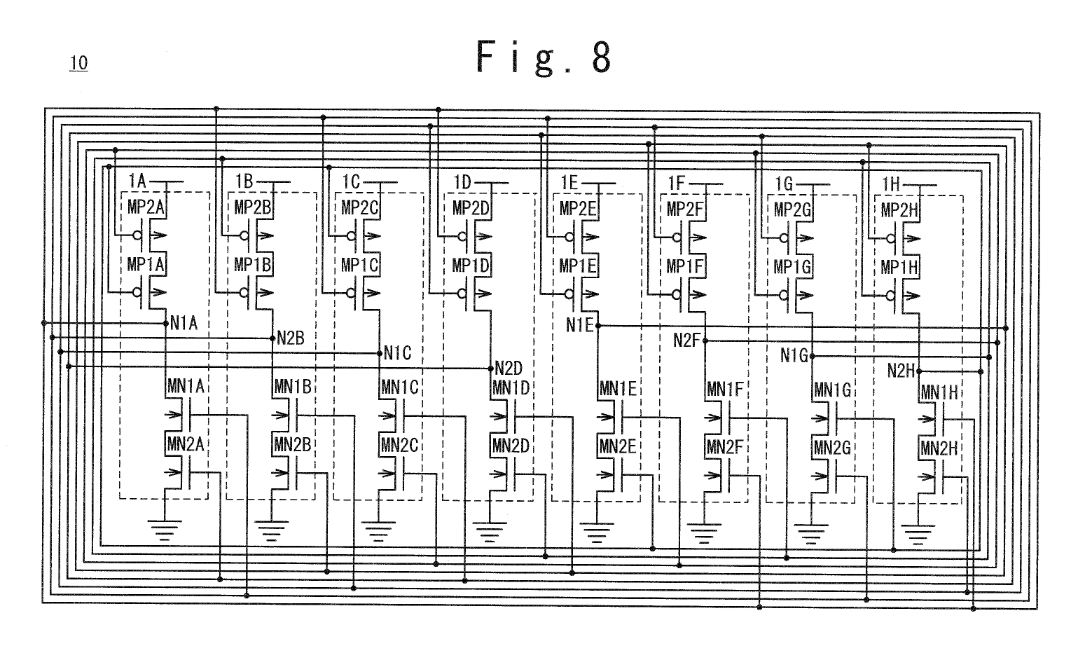

Moreover, any one of the node voltage control circuits 1A to 1H may be reduced from the latch circuit 10 shown in FIG. 4. FIG. 7 is a circuit diagram showing the configuration of the latch circuit 10 according to a third embodiment of the present invention. In the latch circuit 10 shown in FIG. 7, the node voltage control circuits 1G and 1H are removed from the latch circuit 10 shown in FIG. 4. The gates of the P-channel type MOS transistors MP2D and the N-channel type MOS transistors MN2B and MN1F are connected to the node N1E, and gates of the P-channel type MOS transistors MP2A and MP1E and the N-channel type MOS transistor MN2C are connected to the node N2C.

Since in the latch circuit 10 shown in FIG. 7 transistors are removed that cause less influence of noise and nodes whose voltage variation is small are removed, the generation rate of the soft error increases than the circuit shown in FIG. 4, but has an effect of being able to reduce a circuit area. It is effective to use the circuit shown in FIG. 7 instead of the circuit shown in FIG. 4, depending on the requisition of the soft error resistance. It should be noted that the number of the node voltage control circuits to be removed is arbitrary. However, it is preferable that the number of the data holding nodes for holding data of the same vale (the same signal level) is three or more, and the number of the data holding nodes for holding data of an inverted value is three or more. With a configuration like this, one or more nodes that have a small voltage variation and can maintain the signal level becomes able to exist even when the charge collection has occurred in two or more nodes by charge sharing. That is, the generation rate of the soft error can be further reduced than before.

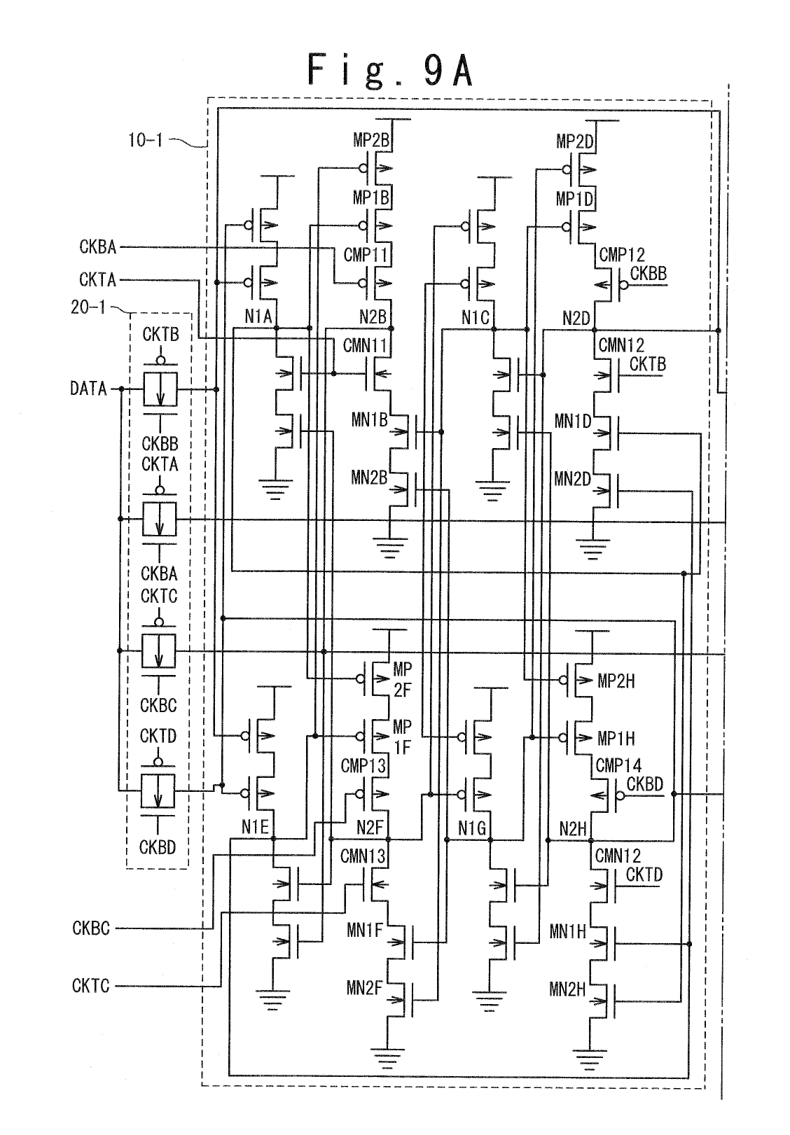

Further, the node voltage control circuits 1A to 1H (gates of the P-channel type MOS transistors MP1A to MN2H) to which the nodes N1A to N214 are connected are not restricted to the form shown in FIG. 4, and may be connected to arbitrary gates of the P-channel type MOS transistors MP1A to MN2H, respectively. For example, it may be connected like the latch circuit 10 shown in FIG. 8.

Here, a connection relationship between the data holding nodes in the latch circuit 10 shown in FIG. 8 and gates of transistors provided in the node voltage control circuit is shown below.

Node N1A: MP1B, MP2D, MN2F, MN1H

Node N1C: MN1B, MP1D, MP1F, MN2H

Node N1E: MN2B, MN1D, MP1F, MP2H

Node N1G: MP2B, MN2D, MN1F, MP1H

Node N2B: MN1A, MP1C, MP2E, MN2G

Node N2D: MN2A, MN1C, MP1E, MP2G

Node N2F: MP2A, MN2C, MN1E, MP1G

Node N2H: MP2A, MP2C, MN2E, MN1G

Also, in the latch circuit 10 shown in FIG. 8, similarly to FIG. 4, one transistor is selected from each of the node voltage control circuits 1B, 1D, 1F, 1H that control voltage values of the nodes N2B, N2D, N2F, and N2H (the second node), and is connected to one of the nodes N1A, N1C, N1E, and N1G. Similarly, one transistor is selected from each of the node voltage control circuits 1A, 1C, 1E, 1G that controls voltage values of the nodes N1A, N1C, N1E and N1G (the first node), and is connected to one of the nodes N2B, N2D, N2F, and N2H. Moreover, the transistors (gates) connected to the data holding nodes are different for every node. Further, the each data holding node is connected to gates of two P-channel type MOS transistors and two N-channel type MOS transistors.

A semiconductor memory device shown in FIG. 8 also operates similarly with the semiconductor memory device in FIG. 4, and consequently the generation rate of the soft error is reduced.

It should be noted that a combination of the data holding node and the gate of the transistor connected to the data holding node can be arbitrarily set up ever, in the form where the node voltage control circuit or the transistor in the node voltage control circuit is reduced.

As one of indices that are used frequently as an index of the easiness of generation of the soft error, critical charge (critical amount of electric charge) is known. The critical charge is a numerical value of a quantity of electric charges at which a data of a specific data holding node being latched is inverted and not returned when electric charges are injected to the data holding node by incidence of radiation, thereby causing the soft error. When this numerical value becomes larger, the soft error will become slower to occur. In order to check the effect of the present invention, the inventor obtained an example of the critical charge through simulation when the electric charges are injected into a plurality of nodes simultaneously by a process of the 90-nm generation. It should be noted that a distribution ratio of electric charges injected to the nodes may differ depending on an incident position and an incident angle of radiation. Here, for simplification, the simulation is performed under the assumption that a same quantity of electric charges is injected to the each data holding node.

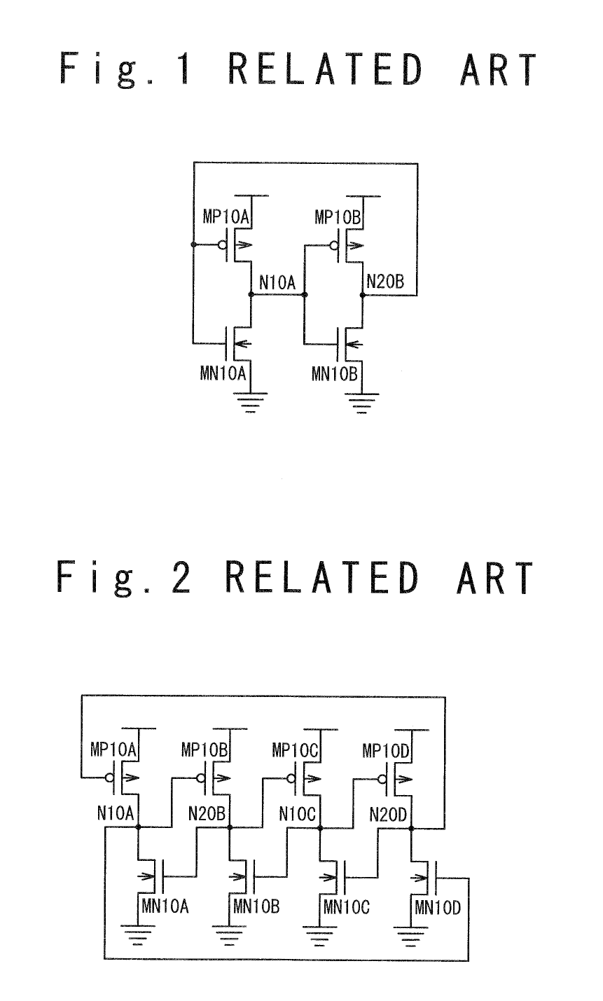

In the latch circuit shown in FIG. 1, when the electric charges were injected into a single data holding node, the critical charge is 4.5 [fC], and it was confirmed that even electric charge injection to the single data holding node causes the soft error to occur. In the DICE shown in FIG. 2, when the electric charges were injected into the single data holding node, the soft error did not occur, and when electric charges were injected into two data holding nodes, the critical charge became 7.5 [fC]. That is, in the conventional DICE, it was confirmed that when the electric charges were injected into two data holding nodes simultaneously, the soft error is generated.

On the other hand, as a result of performing a simulation similarly in the latch circuit 10 shown in FIG. 4, it was confirmed that even if the electric charges were injected into three data holding nodes simultaneously, the soft error did not generate. That is, according to the present invention, even if the electric charges were simultaneously injected into up to three nodes by charge sharing, the soft error did not generate, and so it has been successfully confirmed that it is a circuit having strong resistance to the soft error. It should be noted that if the data holding nodes and the node voltage control circuits are increased in number, it is possible to manufacture a circuit that does not generate the soft error even when charge collection has occurred in still more nodes.

### [Application of the Present Invention]

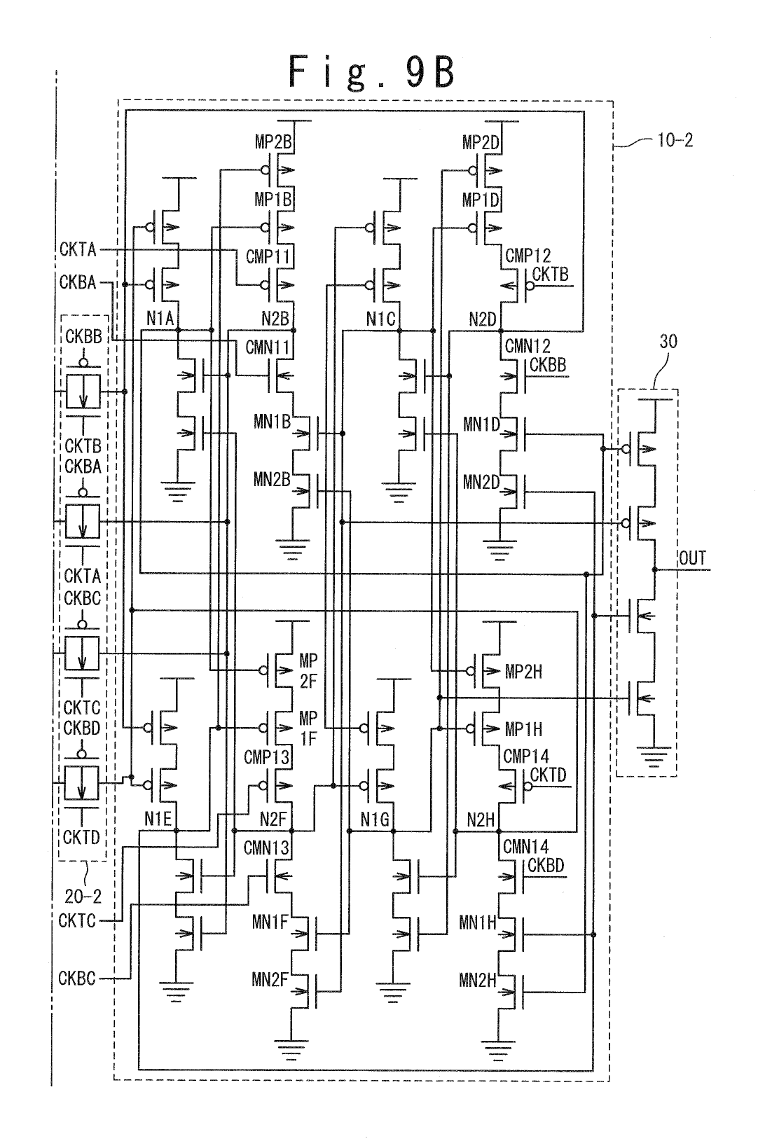

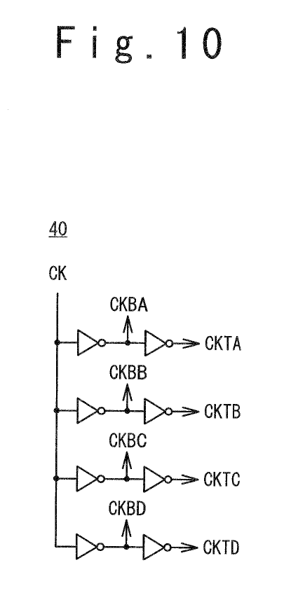

The semiconductor memory device described above is applicable to a flip-flop circuit. FIGS. 9A and 9B are circuit diagrams showing a configuration of the flip-flop circuit using the latch circuits 10 according to the present invention. FIG. 10 is a circuit diagram showing a configuration of a clock signal generating circuit 40 for generating a clock signal to be supplied into the flip-flop circuit.

A configuration of the flip-flop circuit that uses the semiconductor memory device according to the present invention will be described referring to FIGS. 9A, 9B, and 10.

Referring to FIGS. 9A and 9B, the flip-flop circuit has semiconductor circuits 10-1 and 10-2 which have the same configuration as the latch circuit 10 shown in FIG. 4, transfer gate circuits 20-1 and 20-2, and an output circuit 30.

The latch circuits 10-1 and 10-2 have the configuration in which clocked transistors CMP11, CMP12, CMP13, CMP14, CMN11, CMN12, CMN13, and CMN14 are added to the latch circuit 10 shown in FIG. 4, and operate according to the clock signal. Each of the clocked transistors is connected in series between a drain of the transistor connected between the input-side data holding nodes or the output-side data holding nodes (here, the input-side nodes N2B, N2D, N2F, N2H) and the power supply, and the data holding node. For example, the clocked transistor CMP11 is connected between the P-channel type MOS transistor MP1B and the node N2B, and the clocked transistor CMN11 is connected between the N-channel type MOS transistor MN1B and the node N2B. The other clocked transistors are connected similarly.

Clock signals CKBA, CKBB, CKTA, CKTB, CKBC, CKBD, CKTC, and CKTD are respectively supplied to the gates of the clocked transistors CMP11, CMP12, CMP13, CMP14, CMN11, CMN12, CMN13, and CMN14 in a latch circuit 10-1. Similarly, clock signals CKTA, CKTB, CKBA, CKBB, CKTC, CKTD, CKBC, and CKBD are respectively supplied to the gates of the clocked transistors CMP11, CMP12, CMP13, CMP14, CMN11, CMN12, CMN13, and CMN14 in a latch circuit 10-2. The clock signals are generated by the clock signal generating circuit 40 shown in FIG. 10. The clock signals CKBA, CKBB, CKBC, and CKBD are signals with opposite phases to the clock signals CKTA, CKTB, CKTC, and CKTD.

The transfer gate circuit 20-1 is provided with a plurality of transfer gates to which data signal DATA is supplied. Outputs of the plurality of transfer gates are connected to input-side nodes N2B, N2D, N2F, and N2G in the latch circuit 10-1. The data signal DATA is outputted to the nodes N2B, N2D, N2F, and N2G according to the clock signals CKBA, CKBB, CKTA, CKTB, CKBC, CKBD, CKTC, and CKTD.

The transfer gate circuit 20-2 is provided with a plurality of transfer gates to be connected to the output-side nodes N1A, N1C, N1E, and N1G in the latch circuit 10-1. The plurality of transfer gates output the data signal DATA supplied from the nodes N1A, N1C, N1E, and N1G of the latch circuit 10-1 to the input-side nodes N2B, N2D, N2F, and N2G of the latch circuit 10-2 according to the clock signals CKBA, CKBB, CKTA, CKTB, CKBC, CKBD, CKTC, and CKTD.

The output circuit 30 is provided with transistors whose gates are connected to the output-side nodes N2A, N2C, N2E, and N2G of the latch circuit 10-2.

With the above configuration, the flip-flop circuit shown in FIGS. 9A and 9B holds a data signal DATA supplied thereto, and outputs “1” or “0” according to the clock signal. By being provided with the latch circuits 10-1 and 10-2 according to the present invention, the generation rate of soft error in the flip-flop circuit can be reduced.

As described above, the present invention has been described in detail. Specific configurations are not restricted to the above-mentioned embodiments, and even if modifications that do not deviate from a gist of the present invention are given to the embodiment, they are included in the present invention. In the present embodiment, the example that the latch circuit was applied to the flip-flop has been shown. However, application is not restricted to this, for example, and the latch circuit 10 may be applied to a data memory circuit with set/reset. Alternatively, the latch circuit 10 can be used to construct a memory circuit, such as SRAM. Moreover, although the present embodiment has been showed as a form that used the MOS transistor, the present embodiment is not restricted to this as long as an element has a switching function.

What is claimed is:

1. A latch circuit comprising:
first nodes which are three or more and to which a voltage in a first signal level is set;
second nodes which are three or more and to which a voltage in a second signal level obtained by inverting the first signal level is set; and
first node voltage control circuits having said first nodes; and
second node voltage control circuits having said second nodes,
wherein each of said first node voltage control circuits is connected with at least two of said three or more second nodes, and controls the voltage of said first node based on the voltages of said at least two second modes, and
each of said second node voltage control circuits is connected with at least two of said three or more first nodes and controls the voltage of said second node based on the voltages of said at least two first nodes.

2. The latch circuit according to claim 1, wherein said each first node voltage control circuit comprises a first transistor of a first conductive type and a second transistor of a second conductive type whose drains are connected in common to said first node,
said each second node voltage control circuit comprises a third transistor of the first conductive type and a fourth transistor of the second conductive type, whose drains are connected in common to said second node,
gates of said first and second transistors are connected with different ones of said three or more second nodes, respectively, and
gates of said third and fourth transistors are connected with different ones of said three or more first nodes, respectively.

3. The latch circuit according to claim 1, wherein any of said plurality of first node voltage control circuits comprises at least one fifth transistor of the first conductive type which is connected between a source of said first transistor and the first power supply,
gates of said first transistor, said second transistor, and said fifth transistor are connected with different ones of said three or more second nodes, respectively.

4. The latch circuit according to claim 3, wherein four or more said second nodes are provided,
any of said plurality of first node voltage control circuits comprises at least one sixth transistor of the second conductive type which is connected in series between a source of said second transistor and the second power supply through a drain and a source of said sixth transistor,
gates of said firs, second, fifth and sixth transistors are connected with different ones of said four or more second nodes, respectively.

5. The latch circuit according to claim 1, wherein said three or more first nodes are connected with said two or more ones of said plurality of second node voltage control circuits,
said three or more second nodes are connected with two or more ones of said three or more first node voltage control circuits.

6. The latch circuit according to claim 3, wherein each of said three or more first nodes is connected with a gate of a transistor of the first conductive type which is connected between said first power supply and said second node in each of said at least two second node voltage control circuits, and is connected with a gate of a transistor of the second conductive type which is connected between said second power supply and said second node in each of said at least two second node voltage control circuits,
each of said three or more second nodes is connected with a gate of a transistor of the second conductive type which is connected between said first power supply and said first node in each of said at least two first node voltage control circuits, and is connected with a gate of a transistor of the second conductive type which is connected between said second power supply and said first node in each of said at least two first node voltage control circuits.

7. The latch circuit according to claim 1, further comprising:
a plurality of transfer gates connected in correspondence to said three ore more second nodes,
wherein each of said plurality of transfer gates supplies data to a corresponding one of said three or more second nodes.

8. A flip-flop circuit comprising:
a clock signal generating circuit configured to supply a clock signal to said two latch circuits,
a first latch circuit configured to hold a first state corresponding to a first data;
a second latch circuit configured to hold a second state corresponding to a second data;
a first transfer circuit connected with said first latch circuit and configured to supply the first data to said first latch circuit in response to said clock signal;
a second transfer circuit between said first and second latch circuits and configured to transfer the first data from said first latch circuit to said second latch circuit as the second data, and to transfer the second data from said second latch circuit to said first latch circuit as the first data, wherein the second data is obtained by inverting the first data; and
a third transfer circuit configured to output the second data from said second latch circuit,
wherein each of said two latch circuits comprises:
first nodes which are three or more and to which a voltage in a first signal level is set;
second nodes which are three or more and to which a voltage in a second signal level obtained by inverting the first signal level is set; and
first node voltage control circuits having said first nodes; and
second node voltage control circuits having said second nodes,
wherein each of said first node voltage control circuits is connected with at least two of said three or more second nodes, and controls the voltage of said first node based on the voltages of said at least two second modes, and
each of said second node voltage control circuits is connected with at least two of said three or more first nodes and controls the voltage of said second node based on the voltages of said at least two first nodes,
wherein a first one of said two latch circuits function as a latch circuit on an input side in which data is supplied to an input node through a first transfer gate circuit, and a second one thereof functions as a latch circuit on an output side in which the data latched in said input node is outputted, and
said first node of said latch circuit on the input side is connected with said second node of said latch circuit on the output side through said transfer gate in the latch circuit on the output side.

9. The flip-flop circuit according to claim 8, wherein said each first node voltage control circuit comprises a first transistor of a first conductive type and a second transistor of a second conductive type whose drains are connected in common to said first node,
said each second node voltage control circuit comprises a third transistor of the first conductive type and a fourth transistor of the second conductive type, whose drains are connected in common to said second node,
gates of said first and second transistors are connected with different ones of said three or more second nodes, respectively, and
gates of said third and fourth transistors are connected with different ones of said three or more first nodes, respectively.

10. The flip-flop circuit according to claim 8, wherein any of said plurality of first node voltage control circuits comprises at least one fifth transistor of the first conductive type which is connected between a source of said first transistor and the first power supply,
gates of said first transistor, said second transistor, and said fifth transistor are connected with different ones of said three or more second nodes, respectively.

11. The flip-flop circuit according to claim 10, wherein four or more said second nodes are provided,
any of said plurality of first node voltage control circuits comprises at least one sixth transistor of the second conductive type which is connected in series between a source of said second transistor and the second power supply through a drain and a source of said sixth transistor,
gates of said firs, second, fifth and sixth transistors are connected with different ones of said four or more second nodes, respectively.

12. The flip-flop circuit according to claim 8, wherein said three or more first nodes are connected with said two or more ones of said plurality of second node voltage control circuits,
said three or more second nodes are connected with two or more ones of said three or more first node voltage control circuits.

13. The flip-flop circuit according to claim 10, wherein each of said three or more first nodes is connected with a gate of a transistor of the first conductive type which is connected between said first power supply and said second node in each of said at least two second node voltage control circuits, and is connected with a gate of a transistor of the second conductive type which is connected between said second power supply and said second node in each of said at least two second node voltage control circuits,
each of said three or more second nodes is connected with a gate of a transistor of the second conductive type which is connected between said first power supply and said first node in each of said at least two first node voltage control circuits, and is connected with a gate of a transistor of the second conductive type which is connected between said second power supply and said first node in each of said at least two first node voltage control circuits.

14. The flip-flop circuit according to claim 8, further comprising:
a plurality of transfer gates connected in correspondence to said three ore more second nodes,
wherein each of said plurality of transfer gates supplies data to a corresponding one of said three or more second nodes.
